(19) United States
(12) Patent Application Publication
(10) Pub. No.: US 2021/0318062 A1
(43) Pub. Date: Oct. 14, 2021

(54) WARNING SYSTEM FOR WATER-COOLING HEAT DISSIPATION DEVICE

(71) Applicant: BITSPOWER INTERNATIONAL CO., LTD., Changhua County (TW)

(72) Inventor: VINCENT YU, CHANGHUA COUNTY (TW)

(21) Appl. No.: 16/843,109

(22) Filed: Apr. 8, 2020

(51) Int. Cl. F25D 31/00; F25D 29/00; G01L 19/12

(52) U.S. Cl. CPC F25D 31/002; F25D 2700/16; G01L 19/12; F25D 29/008

(57) ABSTRACT

A water-cooling heat dissipation device includes a water tank, a water source, a pump, a pressure detector and a circulation pipe. The water tank includes an outlet/inlet through which water flows. The pressure detector is connected to the outlet/inlet and seals the outlet/inlet. The pressure detector detects the volume of the liquid in the water tank and generates a pressure signal. A warning device includes a temperature detection unit, a volume detection unit, a receiving unit, a processing unit, a display unit and a buzzer. The temperature detection unit detecting the temperature of the liquid in the circulation pipe to generate a temperature signal. The volume detection unit detects the speed of the liquid in the circulation pipe to generate a volume signal. The temperature signal, the volume signal and the pressure signal are monitored to protect water-cooling heat dissipation device by high temperature.

### BACKGROUND OF THE INVENTION

### 1. Fields of the Invention

The present invention relates to a heat dissipation device, and more particularly, to a warning system for a water-cooling heat dissipation device.

### 2. Descriptions of Related Art

The conventional warning system for a water-cooling heat dissipation device known to applicant is connected to the water source and water tank in series connection by a circulation pipe. The warning system further includes an illumination adjustment member, a light detection member, a circuit judgement member, a light emitting member and a warning member. The light emitting member emits a light beam which passes through a passage in which the illumination adjustment member is installed. The light beam reaches the light detection member located on one end of the passage, and a voltage value is therefore generated by the light beam received. The voltage value is compared with a standard voltage value to judge that the water-cooling heat dissipation device is operated normally or not.

The warning system activates the warning member go generates warning sound when the liquid stops to flow or the volume of the liquid is less than a pre-set value. However, there are multiple factors affecting eh fluid volume, such as the change of pressure, the change of temperature and scale attached to the pipe. Leakage is another factor that reduces the volume of the liquid, the liquid pressure and increases temperature. In other words, the users are not able to figure out the change in the internal circulation of the liquid.

When the users receive the warning sound due to the change of the liquid volume, it is too late to check out what exactly happens in time. The high temperature can damage the device in short time.

The present invention intends to provide a warning system for a water-cooling heat dissipation device which allows the users to check the device by multiple values to eliminate the shortcomings mentioned above.

### SUMMARY OF THE INVENTION

The present invention relates to a water-cooling heat dissipation device and comprises a water tank, a water source, a pump, a pressure detector and a circulation pipe. The circulation pipe is connected to the water tank, the water source and the pump. The water tank includes at least one outlet/inlet. The pressure detector is connected to the at least one outlet/inlet and seals the at least one outlet/inlet. The water source is connected to a heat source to absorb heat from the heat source. The pump drives liquid between the water tank and the water source to dissipate heat. The pressure detector detects the liquid in the water tank and generates a pressure signal.

A warning device is connected to the circulation pipe between the water tank and the water source. The warning device includes a temperature detection unit, a volume detection unit, a receiving unit, a processing unit, a display unit and a buzzer. The temperature detection unit detects the temperature of the liquid in the circulation pipe to generate a temperature signal. The volume detection unit detects the speed of the liquid in the circulation pipe to generate a volume signal. The receiving unit is wirelessly and electrically connected to the pressure detector and receives the pressure signal. The processing unit includes a pre-set temperature value, a pre-set volume value and a pre-set pressure value built therein. The processing unit receives and calculates the temperature signal, the volume signal and the pressure signal to obtain a temperature calculation value, a volume calculation value and a pressure calculation value. The temperature calculation value, the volume calculation value and the pressure calculation value are respectively compared with the pre-set temperature value, the pre-set volume value and the pre-set pressure value.

When the temperature calculation value is larger than the pre-set temperature value, the processing unit sends the temperature calculation value to the display unit and activates the buzzer to buzz. When the volume calculation value is smaller than the pre-set volume value, the processing unit sends the volume calculation value to the display unit and activates the buzzer to buzz. When the pressure calculation value is smaller than the pre-set pressure value, the processing unit sends the pressure calculation value to the display unit and activates the buzzer to buzz.

The primary object of the present invention is to provide a warning system for a water-cooling heat dissipation device, wherein the temperature signal, the volume signal and the pressure signal are monitored to protect water-cooling heat dissipation device by high temperature.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a perspective view to show the heat dissipation device of the present invention;

FIG. 2 illustrates the components of the heat dissipation device of the present invention;

FIG. 3 illustrates the components of the warning device of the heat dissipation device of the present invention;

FIG. 4 illustrates that the display unit displays the temperature calculation temperature value and the temperature curve;

FIG. 5 illustrates that the display unit displays the volume calculation temperature value;

FIG. 6 illustrates that the display unit displays the pressure calculation temperature value;

FIG. 7 illustrates that the display unit displays the temperature calculation temperature value and the warning light lights on, and

FIG. 8 illustrates the block diagram of the processing unit, the display unit and the buzzer.

### DETAILED DESCRIPTION OF THE PREFERRED EMBODIMENT

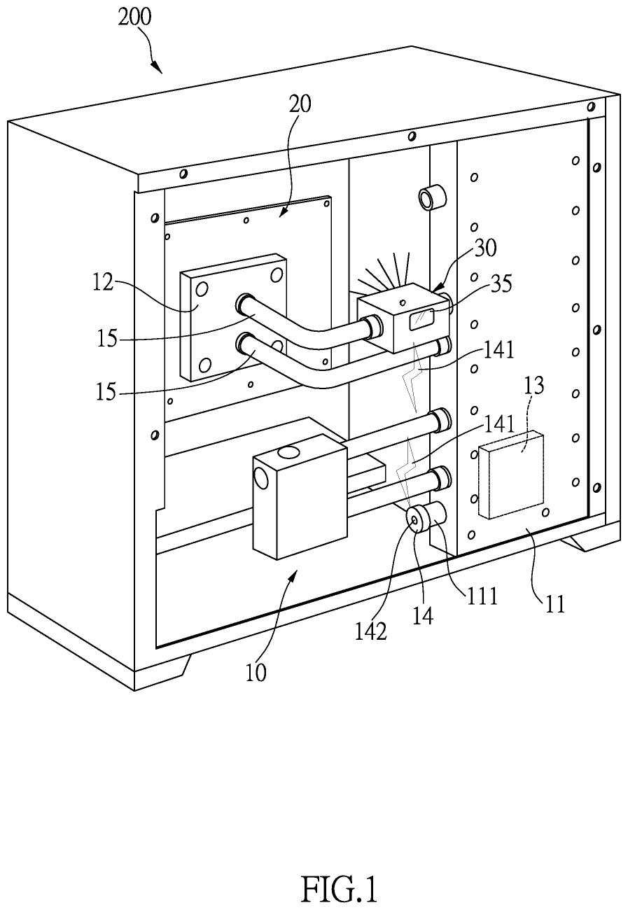

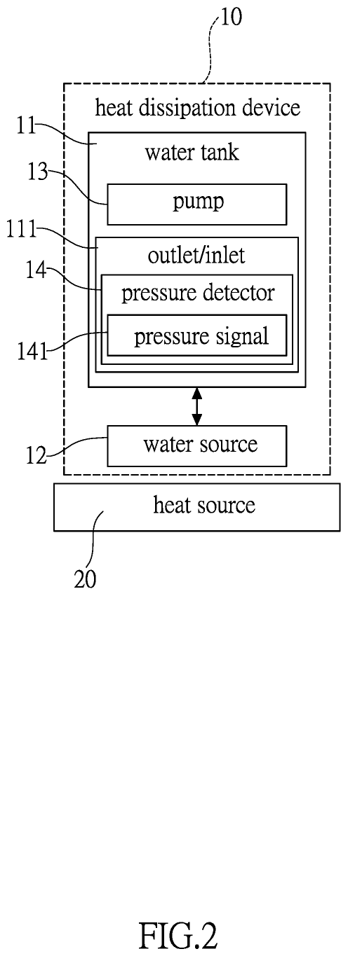

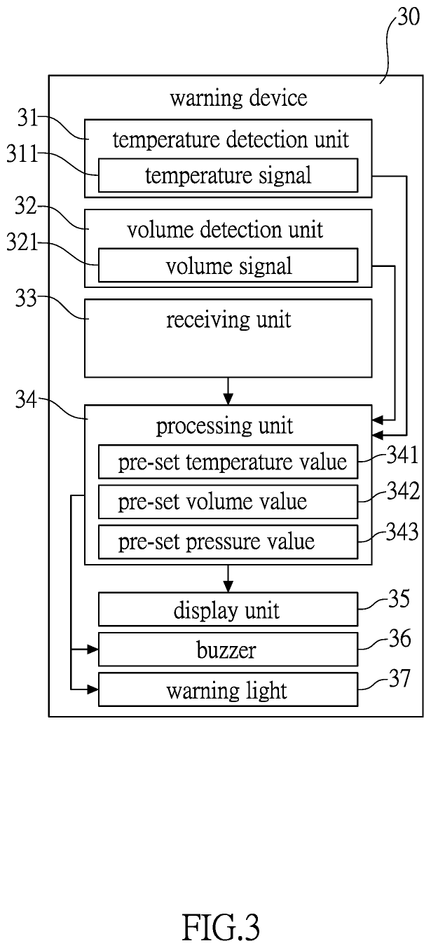

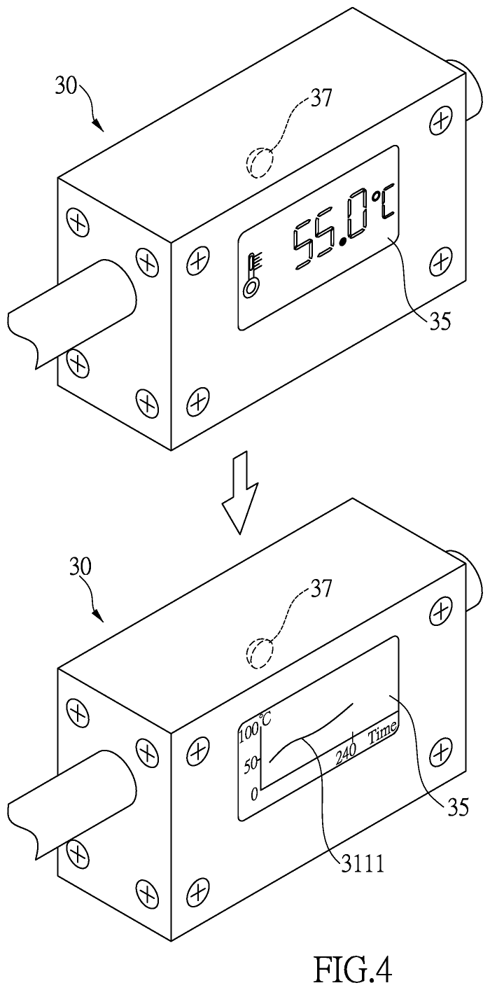

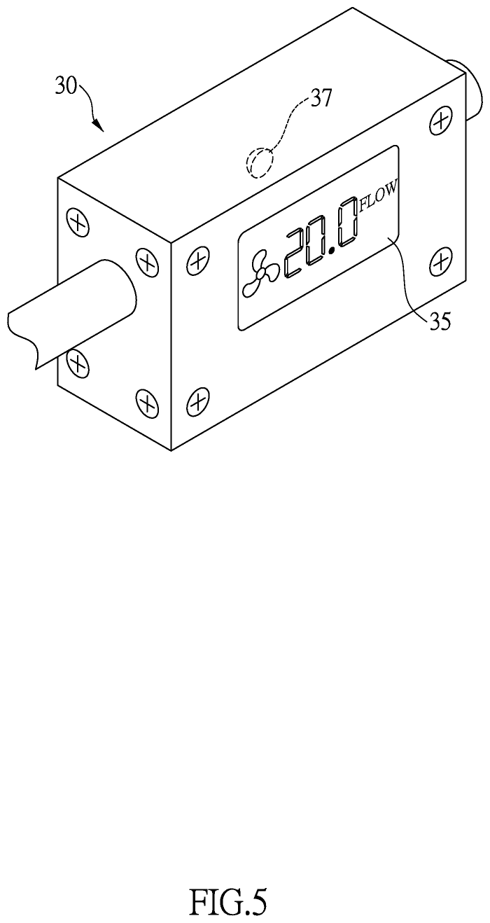

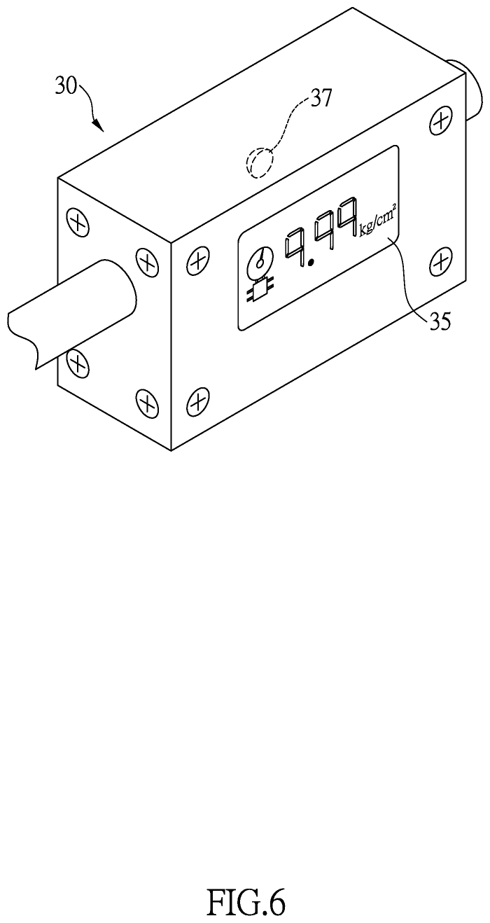

Referring to FIGS. 1 to 6, the water-cooling heat dissipation device 10 of the present invention is installed in a case 200 having a transparent panel, and the water-cooling heat dissipation device 10 comprises a water tank 11, a water source 12, a pump 13, a pressure detector 14 and a circulation pipe 15. The circulation pipe 15 is connected to the water tank 11, the water source 12 and the pump 13. The water tank 11 includes at least one outlet/inlet 111, and the pressure detector 14 is connected to the at least one outlet/inlet 111 and seals the at least one outlet/inlet 111. The water source 12 is connected to a heat source 20 (CPUs or GPUs of a computer) to absorb heat from the heat source 20. The pump 13 drives liquid between the water tank 11 and the water source 12 to dissipate heat. The pressure detector 14 detects the liquid in the water tank 11 and generates a pressure signal 141.

A warning device 30 is connected to the circulation pipe 15 between the water tank 11 and the water source 12. The warning device 30 includes a temperature detection unit 31, a volume detection unit 32, a receiving unit 33, a processing unit 34, a display unit 35 and a buzzer 36. The temperature detection unit 31 detects the temperature of the liquid in the circulation pipe 15 to generate a temperature signal 311. The volume detection unit 32 detects the speed of the liquid in the circulation pipe 15 to generate a volume signal 321. The receiving unit 33 is wirelessly and electrically connected to the pressure detector 14 and receives the pressure signal 141. The processing unit 34 includes a pre-set temperature value 341, a pre-set volume value 342 and a pre-set pressure value 343 built therein. The pre-set temperature value 341, the pre-set volume value 342 and the pre-set pressure value 343 are obtained after the system is operated stably for a period of time. The processing unit 34 receives and calculates the temperature signal 311, the volume signal 321 and the pressure signal 141 to obtain a temperature calculation value, a volume calculation value and a pressure calculation value (not shown). The temperature calculation value, the volume calculation value and the pressure calculation value are respectively compared with the pre-set temperature value 341, the pre-set volume value 342 and the pre-set pressure value 343. When the temperature calculation value is larger than the pre-set temperature value 341, the processing unit 34 sends the temperature calculation value to the display unit 35 and activates the buzzer 36 to buzz. When the volume calculation value is smaller than the pre-set volume value 342, the processing unit 34 sends the volume calculation value to the display unit 35 and activates the buzzer 36 to buzz. When the pressure calculation value is smaller than the pre-set pressure value 343, the processing unit 34 sends the pressure calculation value to the display unit 35 and activates the buzzer 36 to buzz.

That is to say, the processing unit 34 activates the buzzer 36 when either one of the factors as follows is detected, the factors are that the temperature calculation value is larger than the pre-set temperature value 341, the volume calculation value is smaller than the pre-set volume value 342, and the pressure calculation value is smaller than the pre-set pressure value 343. The abnormal situations can be early found and fixed by the multiple factors mentioned above. Therefore, the heat source 20 can be stopped or operated to reduce the temperature thereof to protect the heat source 20 from being damaged by high temperature.

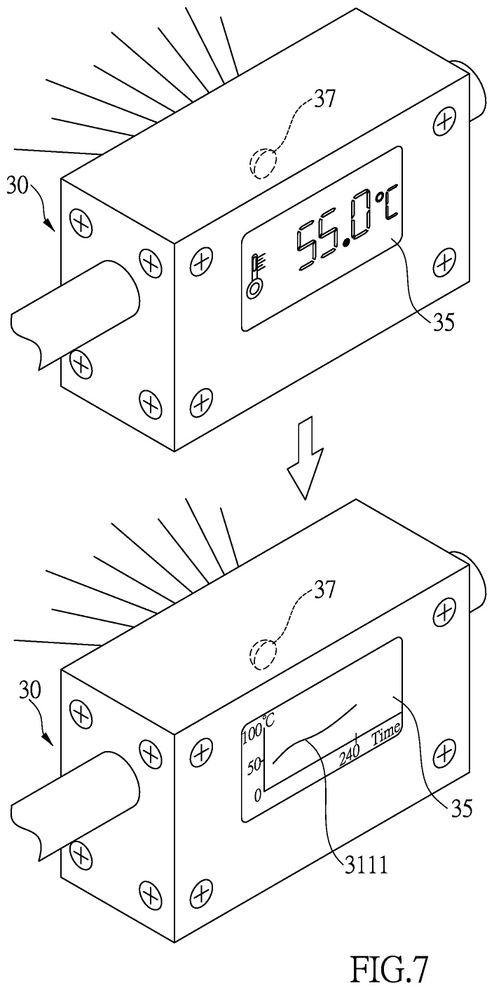

As shown in FIGS. 1 to 7, the processing unit 34 uses the temperature calculation values of the past 240 seconds to form a temperature curve 3111 along the axis, and the temperature curve 3111 is sent to the display unit 35 which alternatively displays the temperature curve 3111 and the latest temperature calculation value to acknowledge the users about the change of temperature for the past 240 seconds. Furthermore, the warning device 30 includes a warning light 37 which is electrically connected to the processing unit 34. The warning light 37 is located opposite to the display unit 35. When the temperature calculation value is larger than the pre-set temperature value 341, the processing unit 34 sends the temperature calculation value to the display unit 35 and lights up the warning light 37, as shown in FIG. 7. When the volume calculation value is smaller than the pre-set volume value 342, the processing unit 34 sends the volume calculation value to the display unit 35 and lights up the warning light 37. When the pressure calculation value is smaller than the pre-set pressure value 343, the processing unit 34 sends the pressure calculation value to the display unit 35 and lights up the warning light 37. When the temperature calculation value is smaller than the pre-set temperature value 341, the display unit 355 is stopped to display. When the volume calculation value is larger than the pre-set volume value 342, the display unit 355 is stopped to display. When the pressure calculation value is larger than the pre-set pressure value 343, the display unit 355 is stopped to display. When the temperature calculation value is smaller than the pre-set temperature value 341, the buzzer 36 is stopped to buzz. When the volume calculation value is larger than the pre-set volume value 342, the buzzer 36 is stopped to buzz. When the pressure calculation value is larger than the pre-set pressure value 343, the buzzer 36 is stopped to buzz. The pump 13 is located in the water tank 11.

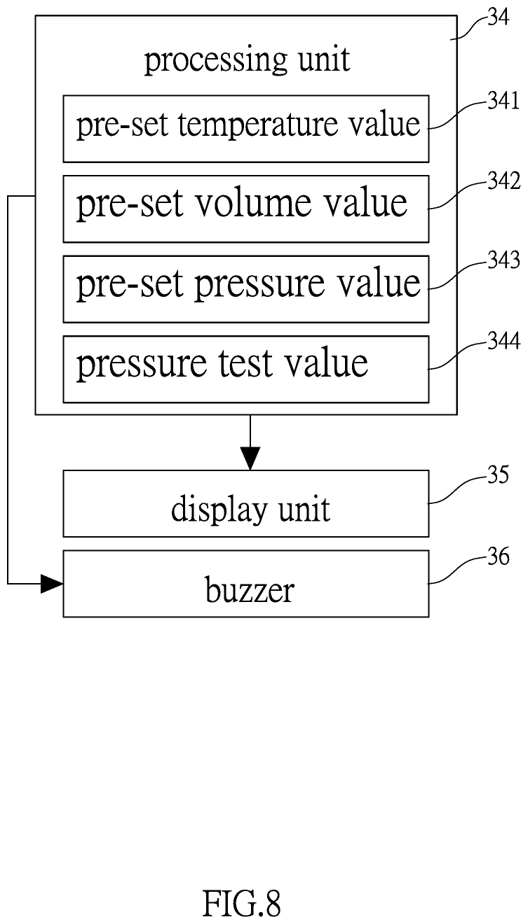

As shown in FIGS. 1-3 and 8, the processing unit 34 includes a pressure test value 344 built therein. The pressure detector 14 includes a one-way air inlet 142 through which pressurized air is introduced. The processing unit 34 calculates the pressure signal 141 after air is introduced from the one-way air inlet 142 to obtain the pressure calculation value, and the pressure calculation value is sent to the display unit 35 which displays the pressure calculation value. The processing unit 34 stops the pressurized air from entering via the one-way air inlet 142 when the buzzer 36 is activated to buzz due to that the pressure calculation value is larger than the pressure test value 344. The processing unit 34 compares the pressure calculation value that is obtained by calculating the pressure signal 141 after 15 seconds from cancelation to the air introduced from the one-way air inlet 142, with the pressure test value 344. When the pressure calculation value is smaller than the pressure test value 344 more than 0.05 kg/cm², the buzzer 36 is activated to buzz to provide a leakage warning.

The water-cooling heat dissipation device of the present invention effectively protects the heat source 20 from being damaged due to operation under high temperature. The life of the heat source 20 can last longer.

While we have shown and described the embodiment in accordance with the present invention, it should be clear to those skilled in the art that further embodiments may be made without departing from the scope of the present invention.

What is claimed is:

1. A water-cooling heat dissipation device comprising:
a water tank, a water source, a pump, a pressure detector and a circulation pipe, the circulation pipe connected to the water tank, the water source and the pump, the water tank having at least one outlet/inlet, the pressure detector connected to the at least one outlet/inlet and sealing the at least one outlet/inlet, the water source connected to a heat source to absorb heat from the heat source, the pump driving liquid between the water tank and the water source to dissipate heat, the pressure detector detecting the liquid in the water tank and generating a pressure signal, and
a warning device connected to the circulation pipe between the water tank and the water source, the warning device including a temperature detection unit, a volume detection unit, a receiving unit, a processing unit, a display unit and a buzzer, the temperature detection unit detecting a temperature of the liquid in the circulation pipe to generate a temperature signal, the volume detection unit detecting a speed of the liquid in the circulation pipe to generate a volume signal, the receiving unit wirelessly and electrically connected to the pressure detector and receiving the pressure signal, the processing unit including a pre-set temperature value, a pre-set volume value and a pre-set pressure value built therein, the processing unit receiving and calculating the temperature signal, the volume signal and the pressure signal to obtain a temperature calculation value, a volume calculation value and a pressure calculation value, the temperature calculation value, the volume calculation value and the pressure calculation value being respectively compared with the pre-set temperature value, the pre-set volume value and the pre-set pressure value, when the temperature calculation value is larger than the pre-set temperature value, the processing unit sends the temperature calculation value to the display unit and activates the buzzer to buzz, when the volume calculation value is smaller than the pre-set volume value, the processing unit sends the volume calculation value to the display unit and activates the buzzer to buzz, when the pressure calculation value is smaller than the pre-set pressure value, the processing unit sends the pressure calculation value to the display unit and activates the buzzer to buzz.

2. The water-cooling heat dissipation device as claimed in claim 1, wherein the processing unit uses the temperature calculation values of the past 240 seconds to form a temperature curve along an axis, and the temperature curve is sent to the display unit which alternatively displays the temperature curve and a latest temperature calculation value.

3. The water-cooling heat dissipation device as claimed in claim 1, wherein the warning device includes a warning light which is electrically connected to the processing unit, the warning light is located opposite to the display unit, when the temperature calculation value is larger than the pre-set temperature value, the processing unit sends the temperature calculation value to the display unit and lights up the warning light.

4. The water-cooling heat dissipation device as claimed in claim 3, wherein when the volume calculation value is smaller than the pre-set volume value, the processing unit sends the volume calculation value to the display unit and lights up the warning light.

5. The water-cooling heat dissipation device as claimed in claim 3, wherein when the pressure calculation value is smaller than the pre-set pressure value, the processing unit sends the pressure calculation value to the display unit and lights up the warning light.

6. The water-cooling heat dissipation device as claimed in claim 1, wherein when the temperature calculation value is smaller than the pre-set temperature value, the display unit is stopped to display, when the volume calculation value is larger than the pre-set volume value, the display unit is stopped to display, when the pressure calculation value is larger than the pre-set pressure value, the display unit is stopped to display.

7. The water-cooling heat dissipation device as claimed in claim 1, wherein when the temperature calculation value is smaller than the pre-set temperature value, the buzzer is stopped to buzz, when the volume calculation value is larger than the pre-set volume value, the buzzer is stopped to buzz, when the pressure calculation value is larger than the pre-set pressure value, the buzzer is stopped to buzz.

8. The water-cooling heat dissipation device as claimed in claim 1, wherein the processing unit includes a pressure test value built therein, the pressure detector includes a one-way air inlet, the processing unit calculates the pressure signal after air is introduced from the one-way air inlet to obtain the pressure calculation value, and the pressure calculation value is sent to the display unit, the processing unit stops the air from entering via the one-way air inlet when the buzzer is activated to buzz due to that the pressure calculation value is larger than the pressure test value, the processing unit compares the pressure calculation value that is obtained by calculating the pressure signal after 15 seconds from cancelation to the air introduced from the one-way air inlet, with the pressure test value, when the pressure calculation value is smaller than the pressure test value more than 0.05 kg/cm², the buzzer is activated to buzz to provide a leakage warning.

9. The water-cooling heat dissipation device as claimed in claim 1, wherein the pump is located in the water tank.
